(19) United States
(12) Patent Application Publication
(10) Pub. No.: US 2026/0223629 A1
(43) Pub. Date: Jul. 30, 2026

(54) TRANSPORTER AND CONNECTION METHOD

(71) Applicant: Tokyo Electron Limited, Tokyo (JP)

(72) Inventors: Ryohei UENO, Miyagi (JP); Dai KITAGAWA, Miyagi (JP); Koei ITO, Miyagi (JP); Masaki KIMURA, Miyagi (JP); Taisei SEGUCHI, Miyagi (JP); Naoki SATO, Miyagi (JP)

(73) Assignee: Tokyo Electron Limited, Tokyo (JP)

(21) Appl. No.: 19/629,394

(22) Filed: Mar. 26, 2026

Related U.S. Application Data
(63) Continuation of application No. PCT/JP2025/021080, filed on Jun. 11, 2025.

(30) Foreign Application Priority Data
Jun. 25, 2024 (JP) 2024-101941

(51) Int. Cl. H10P 72/30; B25J 5/00; G05D 1/24; H10P 72/76

(52) U.S. Cl. CPC H10P 72/3214; B25J 5/00; G05D 1/24; H10P 72/3408; H10P 72/7602

(57) ABSTRACT

A transporter for transporting an object includes a compartment to accommodate the object; an opening portion connectable to a processing apparatus for a substrate; a gate valve to open and close the opening portion; a robotic arm including an end effector, the robotic arm to transfer the object with the end effector to and from the processing apparatus through the opening portion; a first connector structure including a first connector to receive power supplied to the transporter from an external apparatus external to the transporter; a drive to advance the first connector structure toward a second connector structure in the external apparatus to connect the first connector structure to the second connector structure; mover to move the transporter; and controller circuitry to control the drive, and cause the drive to connect the first connector structure to the second connector structure before the opening portion is connected to the processing apparatus.

### CROSS-REFERENCE TO RELATED APPLICATIONS

This application is a continuation of International Application No. PCT/JP 2025/021080, filed on Jun. 11, 2025, which claims the benefit of priority of the prior Japanese Patent Application No. 2024-101941, filed on Jun. 25, 2024, the entire contents of each of which are incorporated herein by reference.

### FIELD

Various aspects and embodiments of the present disclosure relate to a transporter and a connection method.

### BACKGROUND

For example, Japanese Unexamined Patent Application Publication No. 2022-66828 describes a substrate processing apparatus including a first chamber, a substrate support, a second chamber, a clamp, a releaser, and a lifter. The first chamber includes a sidewall having an opening, and further includes a movable portion vertically movable in the first chamber. The substrate support is located in the first chamber. The second chamber is located in the first chamber and defines, together with the substrate support, a processing space in which a substrate received on the substrate support is processed. The second chamber is removable from the first chamber, and is transferable between the internal space of the first chamber and the outside of the first chamber through the opening in the sidewall of the first chamber. The clamp releasably fastens the second chamber to the movable portion extending above the second chamber. The releaser releases the second chamber fastened with the clamp. The lifter vertically moves the movable portion.

For example, Japanese Unexamined Patent Application Publication No. 2021-176173 describes a component replacement system for replacing a wearable component. The component replacement system includes a component container device and a component replacement device. The component container device stores an unused wearable component. The component replacement device connects to a processing apparatus and the component container device and replaces a used wearable component installed in the processing apparatus with the unused wearable component stored in the component container device. The component replacement device moves to the position of the processing apparatus including the wearable component to be replaced and connects to the processing apparatus. The component container device moves to the position of the component replacement device connected to the processing apparatus including the wearable component to be replaced and connects to the component replacement device.

### SUMMARY

A transporter for transporting an object according to one aspect of the present disclosure includes a compartment to accommodate the object; an opening portion connectable to a processing apparatus for processing a substrate; a gate valve to open and close the opening portion; a robotic arm in the compartment, the robotic arm including an end effector at a distal end of the robotic arm, the robotic arm to transfer the object with the end effector to and from the processing apparatus through the opening portion; a first connector structure including a first connector to receive power to be supplied to the transporter from an external apparatus external to the transporter; a drive configured to advance the first connector structure toward a second connector structure in the external apparatus to connect the first connector structure to the second connector structure; mover configured to move the transporter; and controller circuitry configured to control the drive, the controller circuitry configured to cause the drive to connect the first connector structure to the second connector structure before the opening portion is connected to the processing apparatus.

### BRIEF DESCRIPTION OF DRAWINGS

The scope of the present disclosure is best understood from the following detailed description of exemplary embodiments when read in conjunction with the accompanying drawings.

FIG. 1 is a schematic diagram of an example transporter according to one embodiment of the present disclosure.

FIG. 2 is a side view of an example connector unit drive.

FIG. 3 is a plan view of the connector unit drive.

FIG. 4 is a diagram of an example connector unit.

FIG. 5 is a side view of the connector unit drive after the connector unit is advanced.

FIG. 6 is a plan view of the connector unit drive after the connector unit is advanced.

FIG. 7 is a diagram of an example processing apparatus.

FIG. 8 is a flowchart of an example transportation method.

FIG. 9 is a flowchart of the transportation method.

FIG. 10 is a flowchart of the transportation method.

FIG. 11 is a diagram showing an example transportation process.

FIG. 12 is a diagram showing an example transportation process.

FIG. 13 is a diagram showing an example transportation process.

FIG. 14 is a diagram showing an example transportation process.

FIG. 15 is a diagram of a gate valve in the transporter and a gate valve in the processing apparatus, showing an example space between them.

FIG. 16 is a diagram showing an example process of replacing a wearable component.

FIG. 17 is a diagram showing an example transportation process.

FIG. 18 is a diagram showing an example transportation process.

FIG. 19 is a plan view of the connector unit drive in an example state releasing the connection between the connector unit in the transporter and a connector unit in the processing apparatus.

FIG. 20 is a graph showing an example relationship between the travel speed of the transporter and the resistance for climbing over a step.

FIG. 21 is a graph showing an example relationship between the travel speed of the transporter and the maximum acceleration amplitude.

FIG. 22 is a diagram of a surface surrounding an opening portion of the transporter, showing an example state of the surface in contact with an O-ring.

FIG. 23 is a diagram of an example annular member surrounding the opening portion of the transporter.

FIG. 24 is a diagram of the annular member and the O-ring in an example contact state.

FIG. 25 is a diagram of the surface surrounding the opening portion of the transporter and a surface of the processing apparatus receiving the O-ring in an example positional relationship.

FIG. 26 is a diagram of an example seal unit surrounding the opening portion of the transporter.

FIG. 27 is a diagram of the seal unit and the O-ring in an example contact state.

### DESCRIPTION OF EMBODIMENTS

A transporter and a connection method according to one or more embodiments of the present disclosure will now be described below in detail with reference to the drawings. The embodiments below do not limit a transporter and the connection method according to the present disclosure.

A transporter that transports an object such as a wearable component to be used in a semiconductor manufacturing apparatus may include, for example, a robotic arm. The transporter uses power to drive the robotic arm. The transporter receiving power through a cable is movable within the extendable range of the cable.

In contrast, the transporter may receive power from a battery mounted on the transporter. However, the transporter including a small-capacity battery undergoes frequent battery charging, and may not be continuously operable. The transporter including a large-capacity battery is continuously operable, but may be larger. The lager transporter uses a wider path to move through and may increase the overall footprint of a semiconductor manufacturing system.

One or more aspects of the present disclosure are directed to a technique for downsizing the transporter.

### Example Structure of Transporter 10

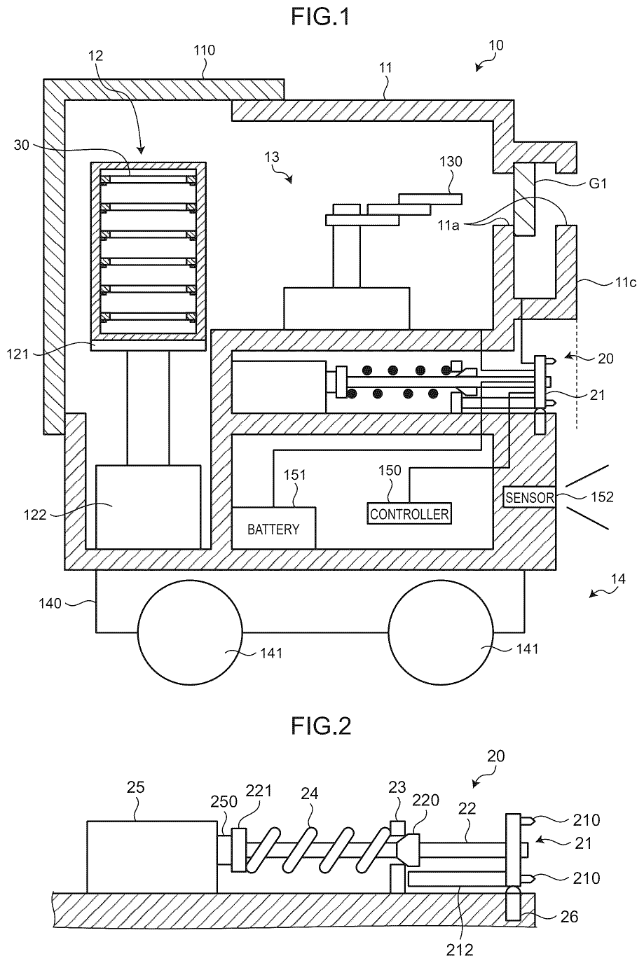

FIG. 1 is a schematic diagram of an example transporter 10 according to one embodiment of the present disclosure. The transporter 10 includes a compartment 11, a cassette 12, a robotic arm 13, a mover 14, and a connector unit drive 20. The compartment 11 accommodates the cassette 12 and the robotic arm 13. The compartment 11 includes a sidewall including an opening portion 11a for loading and unloading a wearable component. The opening portion 11a is opened and closed by a gate valve G1. The opening portion 11a is an example of a first opening portion. The compartment 11 includes a lid 110 that is detached when the cassette 12 is removed from the compartment 11.

The cassette 12 can store an unused wearable component 30 and a used wearable component 30. The cassette 12 is placed on a stage 121. A drive 122 raises and lowers the stage 121. In the present embodiment, the unused wearable component 30 is stored in an upper portion of the cassette 12, and the used wearable component 30 is stored in a lower portion of the cassette 12. The unused wearable component 30 can thus avoid being contaminated with, for example, particles falling from the used wearable component 30. The wearable component 30 is an example of an object.

The robotic arm 13 includes an end effector 130 at the distal end of its arm. The robotic arm 13 uses the end effector 130 to remove a used wearable component 30 from a processing apparatus through the opening portion 11a to store the used wearable component 30 into the cassette 12. The robotic arm 13 also uses the end effector 130 to remove an unused wearable component 30 from the cassette 12 to load the unused wearable component 30 into the processing apparatus through the opening portion 11a.

The connector unit drive 20 controls advancing and retracting of a connector unit 21 that includes multiple connectors (herein “connector unit drive” means the same as “connector drive”). The multiple connectors include, for example, a connector to receive power to be supplied from the processing apparatus and a connector to transmit and receive an electric signal to and from the processing apparatus. The multiple connectors also include, for example, a connector to receive, from the processing apparatus, a gas to be supplied to the transporter 10 and a connector to discharge a gas from the transporter 10 to the processing apparatus.

The connector to receive power to be supplied from the processing apparatus is connected to a flexible cable for charging a battery 151 with the power supplied from the processing apparatus. The connector to transmit and receive an electric signal to and from the processing apparatus is connected to a flexible cable for transmitting the electric signal to a controller 150. The connector to receive, from the processing apparatus, a gas to be supplied to the transporter 10 is connected to a flexible hose for feeding the supplied gas to the components in the transporter 10. The connector to discharge a gas from the transporter 10 to the processing apparatus is connected to a flexible hose for feeding the gas in the transporter 10 to a connector.

When the transporter 10 moves, the connector unit drive 20 retracts the connector unit 21 to a position in the transporter 10 inward from a surface 11c surrounding the opening portion 11a. The surface 11c surrounding the opening portion 11a is an example of an opening surface. In contrast, the connector unit drive 20 advances the connector unit 21 away from the transporter 10 to a position outward from the surface 11c to connect the connector unit 21 to a connector unit in the processing apparatus.

When the moving transporter 10 has the connector unit 21 protruding away from the transporter 10 to a position outward from the surface 11c, the connector unit 21 may come in contact with an obstacle on a movement path while the transporter 10 is moving. When the connector unit 21 comes in contact with an obstacle on the movement path, the connectors included in the connector unit 21 may break or leak electricity through the obstacle.

However, when the transporter 10 moves in the present embodiment, the connector unit drive 20 retracts the connector unit 21 to a position in the transporter 10 inward from the surface 11c. The connectors included in the connector unit 21 are thus less likely to break or leak electricity. Dust or other matter is also less likely to adhere to the connectors included in the connector unit 21.

The mover 14 includes a body 140 and wheels 141. The body 140 includes, for example, a power source and a steering assembly inside. The wheels 141 are rotated by the power source in the body 140 to move the transporter 10 in a direction controlled by the steering assembly in the body 140. The mover 14 for moving the transporter 10 may be any mover such as a walk-behind mover that moves the transporter 10 with a method other than the wheels 141.

The transporter 10 includes the controller 150, the battery 151, and a sensor 152. The sensor 152 senses the surroundings of the transporter 10 and outputs the sensing result to the controller 150 (herein “controller” means the same as “controller circuitry”). The controller 150 includes a storage and a processor. The processor is, for example, a central processing unit (CPU) or a digital signal processor (DSP). The processor reads programs in the storage and executes the programs to control the components of the transporter 10. The controller 150 controls, for example, the mover 14 based on the sensing result from the sensor 152 to move the transporter 10. The controller/controller circuitry 150 can be programmable circuitry (e.g., embedded processor) or fixed circuitry (e.g., ASIC or PAL). In an exemplary embodiment, the controller/controller circuitry 2 can include one or more programmable processors/controllers.

### Structure of Connector Unit Drive 20

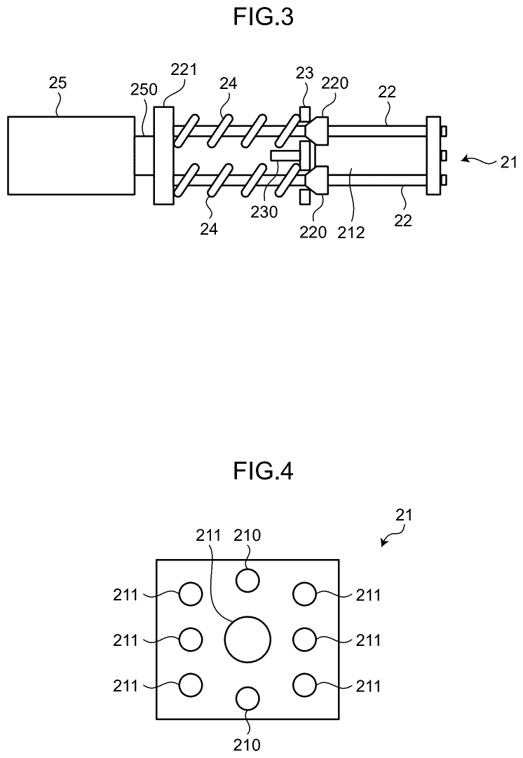

FIG. 2 is a side view of an example of the connector unit drive 20. FIG. 3 is a plan view of the connector unit drive 20. The connector unit drive 20 includes the connector unit 21, guide shafts 22, a bearing 23, springs 24, and a drive 25. As shown in, for example, FIG. 4, the connector unit 21 includes multiple positioning pins 210 and multiple connectors 211. The connector unit 21 is an example of a first connector unit (herein “first connector unit” means the same as “first connector structure”). The positioning pins 210 are each an example of a first positioner.

The positioning pins 210 are placed into the respective positioning holes on the connector unit in the processing apparatus to align the connector unit 21 with the connector unit in the processing apparatus.

The multiple connectors 211 include, for example, the connector to receive power to be supplied from the processing apparatus. The multiple connectors 211 include at least one of the connector to transmit and receive an electric signal to and from the processing apparatus, the connector to receive, from the processing apparatus, a gas to be supplied into the compartment 11, or the connector to discharge a gas from the compartment 11 to the processing apparatus.

The connector to receive power to be supplied from the processing apparatus is an example of a first connector. The connector to transmit and receive an electric signal to and from the processing apparatus is an example of a second connector. The connector to receive, from the processing apparatus, a gas to be supplied to the transporter 10 is an example of a third connector. The connector to discharge a gas from the transporter 10 to the processing apparatus is an example of a fourth connector. The processing apparatus is an example of an external apparatus.

The connector unit 21 includes a plate member 212 in its lower portion. The plate member 212 is supported by a support 26. The support 26 supports the connector unit 21 in a vertically movable manner with the plate member 212. The support 26 is, for example, a ball plunger.

Two guide shafts 22 are connected to the connector unit 21. The two guide shafts 22 are connected with a coupler 221. The two guide shafts 22 extend through through-holes defined in the bearing 23. The bearing 23 and the coupler 221 are located with the springs 24 between them. The bearing 23 and the coupler 221 are urged away from each other with a repulsive force from the springs 24. The bearing 23 includes a stopper 230 to prevent the coupler 221 and the bearing 23 from being too close to each other.

The drive 25 drives a cylinder 250. The drive 25 pushes the cylinder 250 to cause the cylinder 250 to push the coupler 221 in a direction toward the bearing 23. The connector unit 21 is thus pushed with the guide shaft 22. When the drive 25 pulls the cylinder 250 back, the coupler 221 is moved in a direction away from the bearing 23 by a repulsive force from the springs 24 and pulls the connector unit 21 back with the guide shafts 22.

The through-holes in the bearing 23 have an inner diameter larger than the outer diameter of the guide shafts 22. The guide shafts 22 each include a tapered guide 220. When the connector unit 21 is pulled back, the tapered guide enters the corresponding through-hole in the bearing 23 and fills a clearance between the through-hole in the bearing 23 and the guide shaft 22. This can reduce rattling between the bearing 23 and the guide shafts 22 while the transporter 10 is moving.

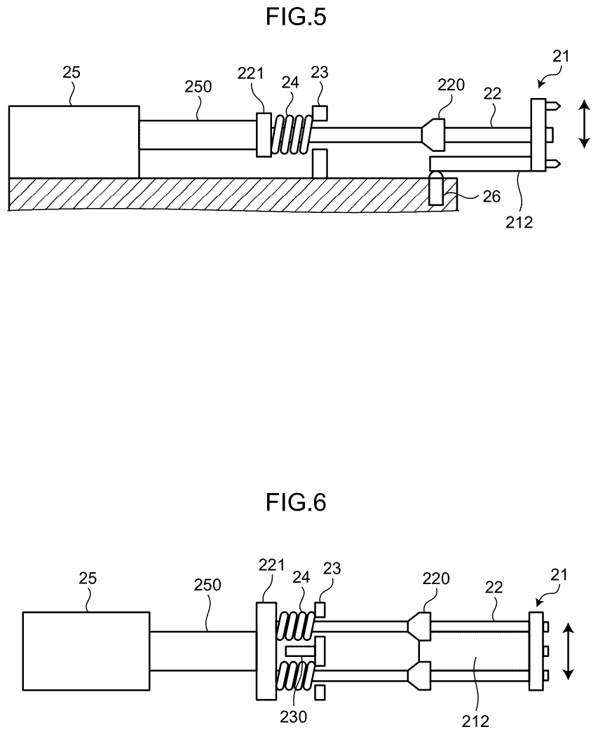

When the drive 25 pushes the cylinder 250 to push the connector unit 21, the tapered guides 220 exit the through-holes in the bearing 23 as shown in, for example, FIGS. 5 and 6. The clearances between the through-holes in the bearing 23 and the guide shafts 22 allows the connector unit 21 to be displaceable in a direction intersecting with the guide shafts 22. In this manner, the positioning pins 210 on the connector unit 21 can be placed into the corresponding positioning holes of the connector unit in the processing apparatus when the position of the connector unit 21 is slightly misaligned from the position of the connector unit in the processing apparatus. The connector unit 21 and the connector unit in the processing apparatus can thus be connected to each other easily.

### Structure of Processing Apparatus 40

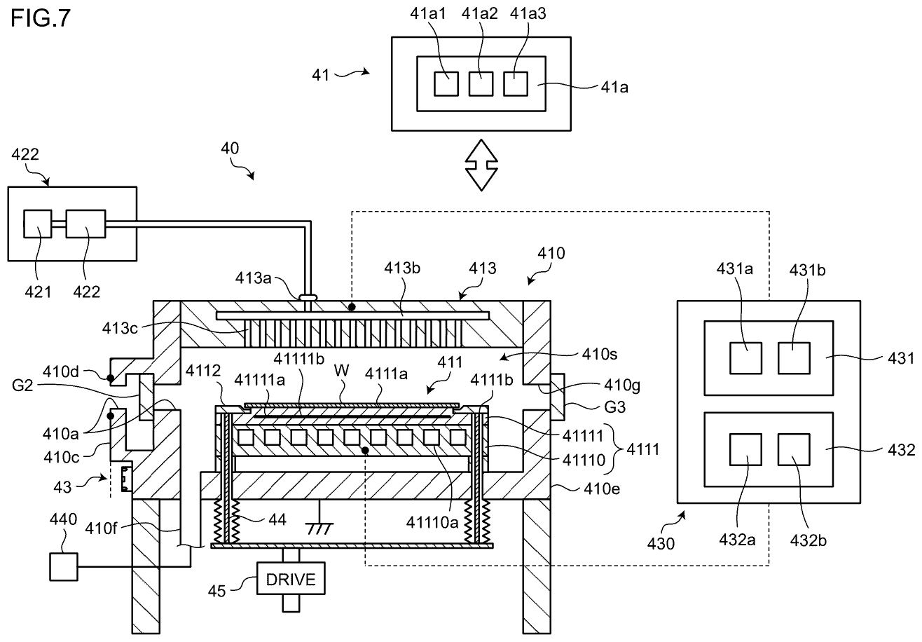

FIG. 7 is a diagram of an example of a processing apparatus 40. The processing apparatus 40 includes a plasma processing chamber 410, a gas supply 420, a power supply 430, and an exhaust system 440. The processing apparatus 40 also includes a substrate support 411 and a gas guide unit. The gas guide unit allows at least one processing gas to be introduced into the plasma processing chamber 410. The gas guide unit includes a showerhead 413. The substrate support 411 is located in the plasma processing chamber 410. The showerhead 413 is located above the substrate support 411. In one embodiment, the showerhead 413 defines at least a part of the ceiling of the plasma processing chamber 410. The plasma processing chamber 410 has a plasma processing space 410s defined by the showerhead 413, a sidewall 410e of the plasma processing chamber 410, and the substrate support 411.

The plasma processing chamber 410 has at least one gas inlet for supplying at least one processing gas into the plasma processing space 410s and at least one gas outlet to discharge the gas from the plasma processing space. The plasma processing chamber 410 is grounded. The showerhead 413 and the substrate support 411 are electrically insulated from the housing of the plasma processing chamber 410. The plasma processing chamber 410 includes, in its sidewall 410e, an opening portion 410a used to load and unload a wearable component into and from the plasma processing chamber 410. The plasma processing chamber 410 includes, in its sidewall 410e, an opening portion 410g used to load and unload a substrate W into and from the plasma processing chamber 410 through a vacuum transfer chamber. The opening portion 410g is different from the opening portion 410a. The opening portion 410a is opened and closed by a gate valve G2. The opening portion 410g is opened and closed by a gate valve G3. The opening portion 410a is surrounded by an O-ring 410d on a surface 410c surrounding the opening portion 410a. A connector unit 43 is located below the opening portion 410a. The connector unit 43 includes, for example, a connector to supply, for example, power to the transporter 10. The connector unit 43 includes a positioner engageable with the positioning pins 210 on the connector unit 21 in the transporter 10. The opening portion 410a is an example of a second opening portion. The connector unit 43 is an example of a second connector unit (herein “second connector unit” means the same as “second connector structure”). The positioner in the connector unit 43 is an example of a second positioner.

The substrate support 411 includes a body 4111 and a ring assembly 4112. The body 4111 includes a central portion 4111a for supporting the substrate W and an annular portion 4111b for supporting the ring assembly 4112. A wafer is an example of the substrate W. The annular portion 4111b of the body 4111 surrounds the central portion 4111a of the body 4111 as viewed in plan. The substrate W is placeable on the central portion 4111a of the body 4111. The ring assembly 4112 is located on the annular portion 4111b of the body 4111 to surround the substrate W on the central portion 4111a of the body 4111. Thus, the central portion 4111a is also referred to as a substrate support surface for supporting the substrate W. The annular portion 4111b is also referred to as a ring support surface for supporting the ring assembly 4112.

In one embodiment, the body 4111 includes a base 41110 and an electrostatic chuck (ESC) 41111. The base 41110 includes a conductive member. The conductive member in the base 41110 may function as a lower electrode. The ESC 41111 is located above the base 41110. The ESC 41111 includes a ceramic member 41111a and an electrostatic electrode 41111b located inside the ceramic member 41111a. The ceramic member 41111a includes the central portion 4111a. In one embodiment, the ceramic member 41111a also includes the annular portion 4111b. The annular portion 4111b may be included in another member surrounding the ESC 41111, such as an annular ESC or an annular insulating member. In this case, the ring assembly 4112 may be located on the annular ESC or the annular insulating member, or may be located on both the ESC 41111 and the annular insulating member. At least one radio-frequency (RF)/direct current (DC) electrode coupled to an RF power supply 431 or a DC power supply 432 (described later) may be located inside the ceramic member 41111a. In this case, at least one RF/DC electrode functions as a lower electrode. When a bias RF signal or a DC signal, or both (described later) are provided to at least one RF/DC electrode, the RF/DC electrode is also referred to as a bias electrode. The conductive member in the base 41110 and at least one RF/DC electrode may function as multiple lower electrodes. The electrostatic electrode 41111b may also function as a lower electrode. The substrate support 411 thus includes at least one lower electrode.

The ring assembly 4112 includes one or more annular members (hereinafter “annular member/members” means the same as “annular structure/structures”). In one embodiment, the one or more annular members include one or more edge rings and at least one cover ring. The edge rings are formed from a conductive material or an insulating material. The cover ring is formed from an insulating material.

The substrate support 411 may include a temperature controller that adjusts the temperature of at least one of the ESC 41111, the ring assembly 4112, or the substrate to a target temperature. The temperature controller may include a heater, a heat transfer medium, a channel 41110a, or a combination of these. The channel 41110a carries a heat transfer fluid such as brine or a gas. In one embodiment, the channel 41110a is defined inside the base 41110, and one or more heaters are located in the ceramic member 41111a of the ESC 41111. The substrate support 411 may include a heat transfer gas supply that supplies a heat transfer gas into a space between the back surface of the substrate W and the central portion 4111a.

The bottom of the plasma processing chamber 410 and the body 41111 of the substrate support 411 have through-holes through which lift pins 44 extend. The lift pins 44 are raised and lowered by the drive 45 to replace the ring assembly 4112. A used ring assembly 4112 can thus be transferred to the robotic arm 13 of the transporter 10 and unloaded from the plasma processing chamber 410. An unused ring assembly 4112 loaded into the plasma processing chamber 410 can be received from the robotic arm 13 and placed on the ESC 41111.

The showerhead 413 introduces at least one processing gas from the gas supply 420 into the plasma processing space 410s. The showerhead 413 includes at least one gas inlet 413a, at least one gas-diffusion compartment 413b, and multiple gas guides 413c. The processing gas supplied to the gas outlet 413a passes through the gas-diffusion compartment 413b and is introduced into the plasma processing space 410s through the gas guides 413c. The showerhead 413 further includes at least one upper electrode. In addition to the showerhead 413, the gas guide unit may include one or more side gas injectors (SGIs) installed in one or more opening portions in the sidewall 410e.

The gas supply 420 may include at least one gas source 421 and at least one flow controller 422. In one embodiment, the gas supply 420 supplies at least one processing gas from each gas source 421 to the showerhead 413 through the corresponding flow controller 422. The flow controller 422 may include, for example, a mass flow controller or a pressure-based flow controller. The gas supply 420 may further include one or more flow rate modulators that cause at least one processing gas to be supplied at a modulated flow rate or in a pulsed manner.

The power supply 430 includes an RF power supply 431 coupled to the plasma processing chamber 410 through at least one impedance matching circuit. The RF power supply 431 provides at least one RF signal (RF power) to at least one lower electrode or at least one upper electrode, or both. This generates a plasma from at least one processing gas supplied into the plasma processing space 410s. The RF power supply 431 may thus function as at least a part of a plasma generator that generates a plasma from one or more processing gases in the plasma processing chamber 410. A bias RF signal is provided to at least one lower electrode to generate a bias potential in the substrate W, thus drawing ion components in the generated plasma toward the substrate W.

In one embodiment, the RF power supply 431 includes a first RF generator 431a and a second RF generator 431b. The first RF generator 431a is coupled to at least one lower electrode or at least one upper electrode, or both through at least one impedance matching circuit to generate a source RF signal (source RF power) for plasma generation. In one embodiment, the source RF signal has a frequency in a range of 10 to 150 MHz. In one embodiment, the first RF generator 431a may generate multiple source RF signals with different frequencies. The one or more generated source RF signals are provided to at least one lower electrode or at least one upper electrode, or both.

The second RF generator 431b is coupled to the at least one lower electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 431b may generate multiple bias RF signals with different frequencies. The one or more generated bias RF signals are provided to at least one lower electrode. In various embodiments, at least one of the source RF signal or the bias RF signal may be pulsed.

The power supply 430 may include a DC power supply 432 coupled to the plasma processing chamber 410. The DC power supply 432 includes a first DC generator 432a and a second DC generator 432b. In one embodiment, the first DC generator 432a is coupled to at least one lower electrode to generate a first DC signal. The generated first bias DC signal is applied to at least one lower electrode. In one embodiment, the second DC generator 432b is coupled to at least one upper electrode to generate a second DC signal. The generated second DC signal is applied to at least one upper electrode.

In various embodiments, at least one of the first DC signal or the second DC signal may be pulsed. In this case, the sequence of voltage pulses is applied to at least one lower electrode or at least one upper electrode, or both. The voltage pulses may have rectangular, trapezoidal, or triangular pulse waveform, or a combination of these. In one embodiment, a waveform generator for generating a sequence of voltage pulses based on DC signals is coupled between the first DC generator 432a and at least one lower electrode. Thus, the first DC generator 432a and the waveform generator form a voltage pulse generator. When the second DC generator 432b and the waveform generator form a voltage pulse generator, the voltage pulse generator is coupled to at least one upper electrode. The voltage pulses may have positive polarity or negative polarity. The sequence of the voltage pulses may include one or more positive voltage pulses and one or more negative voltage pulses within one cycle. The power supply 430 may include the first DC generator 432a and the second DC generator 432b in addition to the RF power supply 431 or may include the first DC generator 432a in place of the second RF generator 431b.

The exhaust system 440 is connectable to, for example, a gas outlet 410f located at the bottom of the plasma processing chamber 410. The exhaust system 440 may include a pressure control valve and a vacuum pump. The pressure control valve regulates the pressure in the plasma processing space 410s. The vacuum pump may be a turbomolecular pump, a dry pump, or a combination of these.

The controller 41 processes computer-executable instructions that cause the processing apparatus 40 to perform various steps described in one or more embodiments of the present disclosure (herein “controller” means the same as “controller circuitry”). The controller 41 may control the components of the processing apparatus 40 to perform the various steps described herein. In one embodiment, some or all of the components of the controller 41 may be included in the processing apparatus 40. The controller 41 may include a processor 41a1, a storage 41a2, and a communication interface 41a3. The controller 41 is implemented by, for example, a computer 41a. The processor 41a1 may perform various control operations by loading programs from the storage 41a2 and executing the loaded programs. The programs may be prestored in the storage 41a2 or may be obtained through a medium as appropriate. The obtained programs are stored into the storage 41a2 to be loaded from the storage 41a2 and executed by the processor 41a1. The medium may be one of various storage media readable by the computer 41a or a communication line connected to the communication interface 41a3. The processor 41a1 may be a CPU. The storage 41a2 may include a random-access memory (RAM), a read-only memory (ROM), a hard disk drive (HDD), a solid-state drive (SSD), or a combination of these. The communication interface 41a3 may communicate with the processing apparatus 40 through a communication line such as a local area network (LAN). The controller/controller circuitry 41 can be programmable circuitry (e.g., embedded processor) or fixed circuitry (e.g., ASIC or PAL). In an exemplary embodiment, the controller/controller circuitry 2 can include one or more programmable processors/controllers.

### Transportation Method

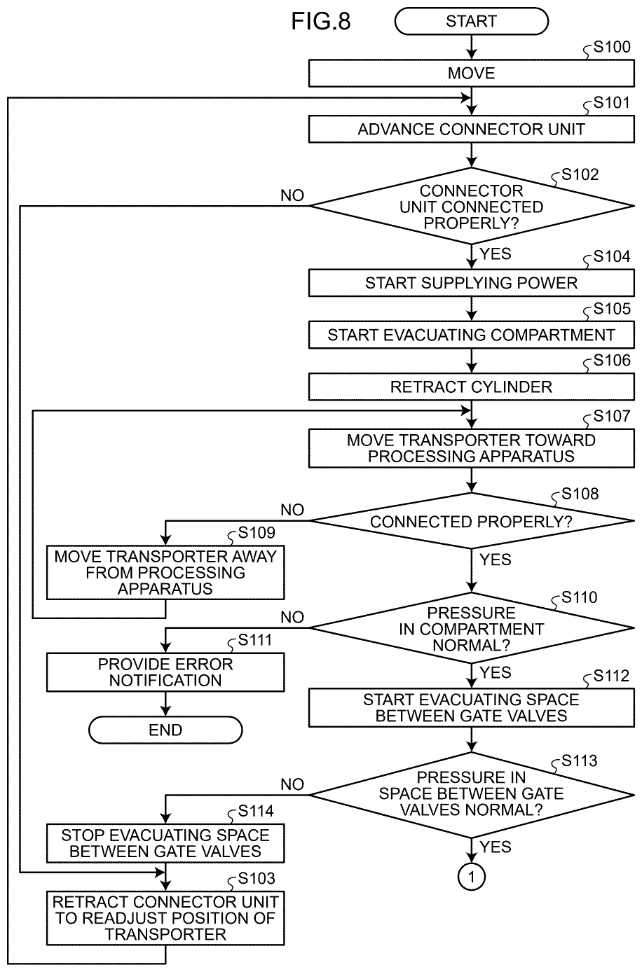

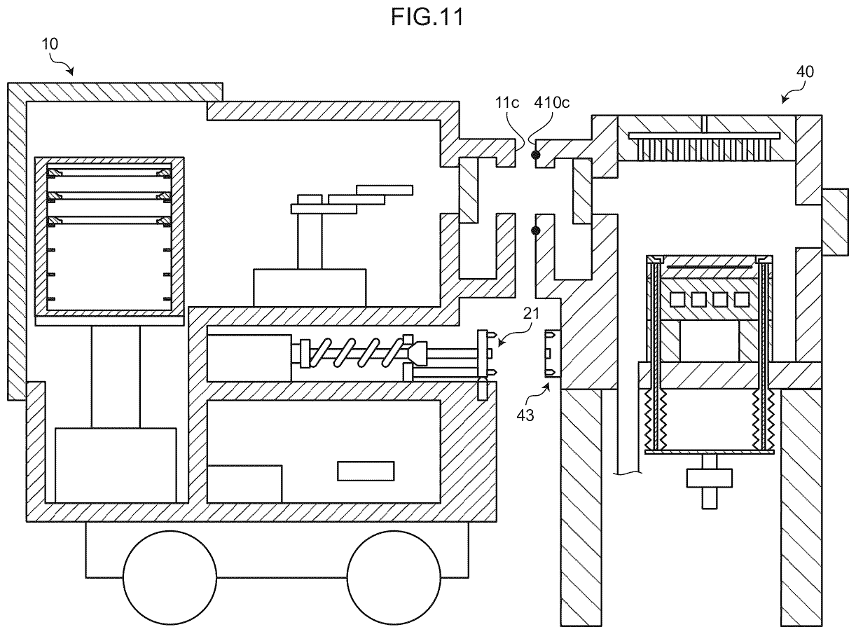

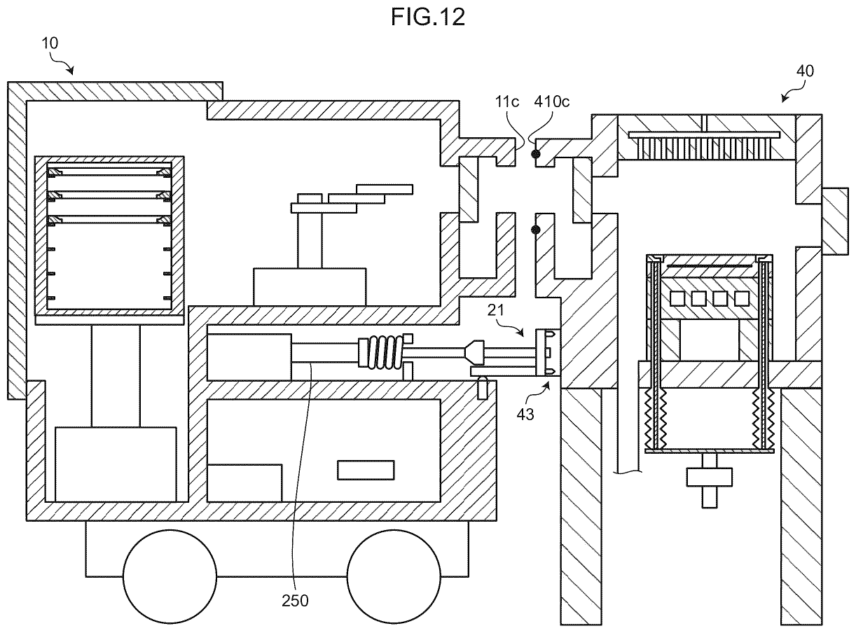

FIGS. 8 to 10 are flowcharts of an example transportation method. The transportation method illustrated in FIGS. 8 to 10 is implemented by the controller 150 controlling the components of the transporter 10. The transportation method in one example will be described below with reference to FIGS. 11 to 19. The transportation method illustrated in FIGS. 8 to 10 is an example of a connection method.

The mover 14 first moves the transporter 10 to a position adjacent to the processing apparatus 40 (step S100). Step S100 is an example of step (a). The transporter 10 thus moves to a position adjacent to the processing apparatus 40 as shown in, for example, FIG. 11. The surface 11c surrounding the opening portion 11a of the transporter 10 faces the surface 410c surrounding the opening portion 410a of the processing apparatus 40.

The connector unit drive 20 in the transporter 10 then advances the connector unit 21 (step S101). Step S101 is an example of step (b). In step S101, the connector unit drive 20 advances, with the drive 25, the connector unit 21 toward the connector unit 43 in the processing apparatus 40 and connects the connector unit 21 to the connector unit 43 as shown in, for example, FIG. 12.

The determination is then performed as to whether the connector unit 21 is connected properly (step S102). In step S102, the controller 150 determines, for example, whether the load on the drive 25 is within a normal range. For example, the controller 150 determines whether an electric signal indicating that the connector unit 21 has been connected properly is received from the processing apparatus 40 through the connectors 211 in the connector unit 21. For example, the connector unit 43 in the processing apparatus 40 includes a sensor. When the sensor outputs an electric signal indicating a proper connection, the controller 41 in the processing apparatus 40 transmits, to the transporter 10 through the connector unit 43 and the connector unit 21, an electric signal indicating that the connector unit 21 has been connected properly.

When the connector unit 21 is not connected properly (No in step S102), the connector unit drive 20 drives the drive 25 to retract the connector unit 21. The step of connecting the connector unit 21 properly is an example of step (c). The controller 150 then controls the mover 14 to readjust the position of the transporter 10 relative to the processing apparatus 40 (step S103).

In step S102, when, for example, the load on the drive 25 is outside the normal range or no electric signal indicating that the connector unit 21 has been connected properly is received from the processing apparatus 40, the connector unit 21 is determined as not being connected properly. When the connector unit 21 is determined as not being connected properly a predetermined number of times or more in step S102, an error notification is provided to, for example, an administrator of the transporter 10, and the transportation method shown in the flowchart ends.

In response to the connector unit 21 being connected properly (Yes in step S102), the processing apparatus 40 starts supplying power to the transporter 10 through the connector unit 21 (step S104). Evacuation of the compartment 11 is then started through the connector unit 21 (step S105). In step S105, the controller 150 in the transporter 10 transmits, through the connector unit 21 and the connector unit 43, an electric signal to instruct the controller 41 in the processing apparatus 40 to evacuate the compartment 11 using the exhaust system 440. This starts the evacuation of the compartment 11. The evacuation of the compartment 11 is started using a flexible hose connected to the compartment 11, the connector unit 21, the connector unit 43, and the exhaust system 440.

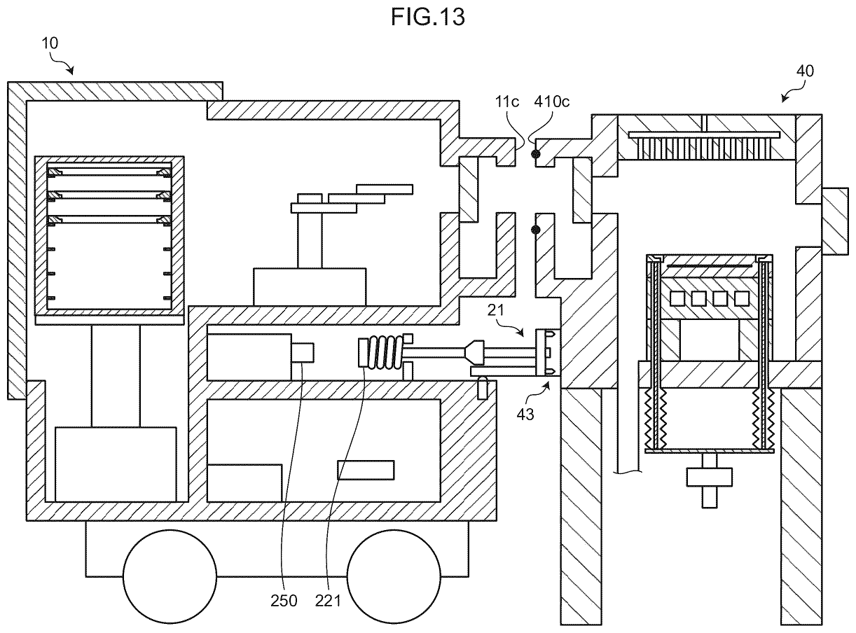

The drive 25 then retracts the cylinder 250 (step S106). In step S106, the drive 25 retracts the cylinder 250 to separate the cylinder 250 from the coupler 221 as shown in, for example, FIG. 13.

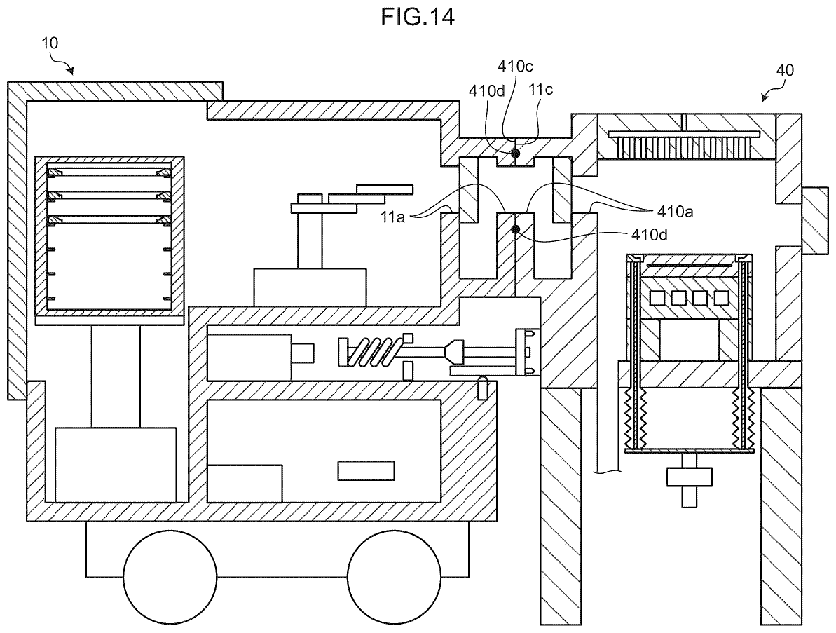

The mover 14 then moves the transporter 10 toward the processing apparatus 40 (step S107). Step S107 is an example of step (d). In step S107, the transporter 10 moves toward the processing apparatus 40. This connects the surface 11c surrounding the opening portion 11a of the transporter 10 to the surface 410c surrounding the opening portion 410a of the processing apparatus 40 with the O-ring 410d between them as shown in, for example, FIG. 14.

The determination is then performed as to whether the opening portion 11a of the transporter 10 is properly connected to the opening portion 410a of the processing apparatus 40 (step S108). In step S108, the controller 150 determines, for example, whether an electric signal indicating that the opening portion 11a of the transporter 10 has been properly connected to the opening portion 410a of the processing apparatus 40 is received from the processing apparatus 40 through the connectors 211 in the connector unit 21. For example, a sensor is attached to the surface 410c surrounding the opening portion 410a of the processing apparatus 40. When the sensor outputs an electric signal indicating a proper connection, the controller 41 in the processing apparatus 40 transmits an electric signal indicating that the opening portion 11a of the transporter 10 has been properly connected to the opening portion 410a of the processing apparatus 40 to the transporter 10 through the connector units.

In response to a determination that the opening portion 11a of the transporter 10 is not properly connected to the opening portion 410a of the processing apparatus 40 (No in step S108), the mover 14 moves the transporter 10 away from the processing apparatus 40 (step S109). The mover 14 then adjusts the position of the transporter 10 relative to the processing apparatus 40, and the processing in step S107 is performed again.

In response to a determination that the opening portion 11a of the transporter 10 is properly connected to the opening portion 410a of the processing apparatus 40 (Yes in step S108), the determination is performed as to whether the pressure in the compartment 11 is normal (step S110). The gas in the compartment 11 is discharged by the exhaust system 440 in the processing apparatus 40 through the connector unit 21 and the connector unit 43. A pipe between the connector unit 43 and the exhaust system 440 includes a pressure sensor. The controller 41 in the processing apparatus 40 transmits the measurement value from the pressure sensor to the transporter 10 through the connector unit 43 and the connector unit 21. In step S110, the determination is performed, for example, as to whether the controller 150 has received, from the processing apparatus 40, an electric signal indicating that the pressure in the compartment 11 has reached or fallen below a predetermined pressure within a predetermined period after the start of evacuating the compartment 11 in step S105.

In response to the pressure in the compartment 11 being abnormal (No in step S110), an error notification is provided to, for example, the administrator of the transporter 10 (step S111), and the transportation method shown in the flowchart ends.

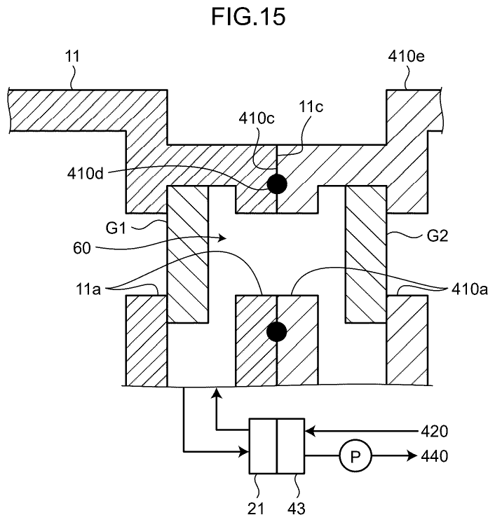

In response to the pressure in the compartment 11 being normal (Yes in step S110), evacuation of the space between the gate valves is started (step S112). In step S112, the controller 150 in the transporter 10 transmits, through the connector unit 21 and the connector unit 43, an electric signal to instruct the controller 41 in the processing apparatus 40 to evacuate the space between the gate valves using the exhaust system 440. The exhaust system 440 thus starts discharging a gas in a space 60 between the gate valve G1 in the transporter 10 and the gate valve G2 in the processing apparatus 40 through the connector unit 21 and the connector unit 43 as shown in, for example, FIG. 15.

The determination is then performed as to whether the pressure in the space between the gate valves is normal (step S113). The pipe between the connector unit 43 and the exhaust system 440 includes a pressure sensor P as shown in, for example, FIG. 15. In step S113, the controller 41 in the processing apparatus 40 transmits the measurement value from the pressure sensor P to the transporter 10 through the connector unit 43 and the connector unit 21. In step S113, the controller 150 determines, for example, whether the pressure in the space 60 has reached or fallen below a predetermined pressure within a predetermined period after the start of evacuating the space 60 between the gate valve G1 and the gate valve G2 in step S112.

In response to the pressure in the space 60 between the gate valves being abnormal (No in step S113), the evacuation of the space 60 between the gate valves is stopped (step S114), and the processing in step S103 is performed. When the pressure in the space 60 between the gate valves is determined as abnormal a predetermined number of times or more in step S113, an error notification is provided to, for example, the administrator of the transporter 10, and the transportation method shown in the flowchart ends.

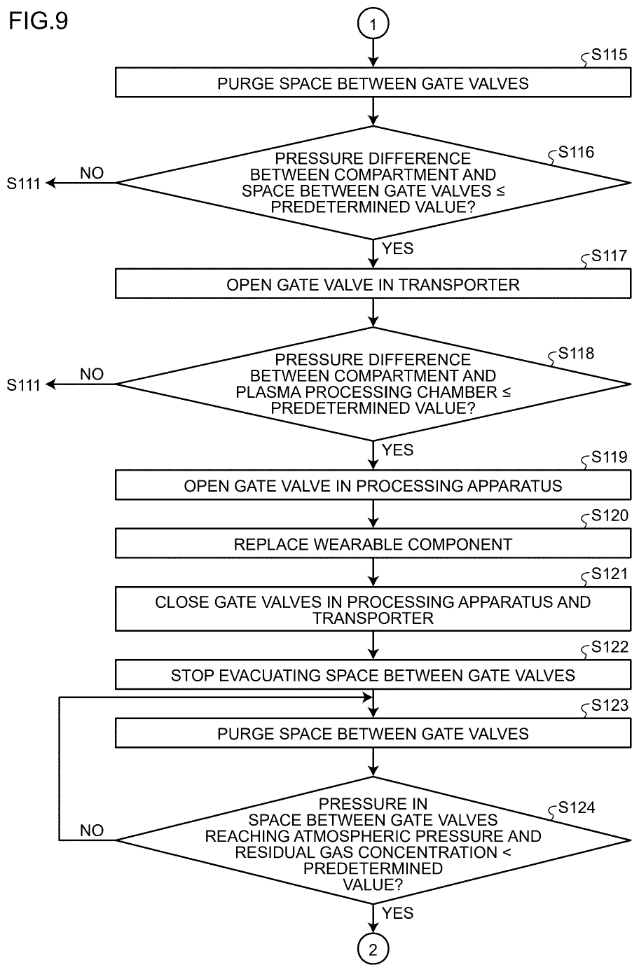

In response to the pressure in the space 60 between the gate valves being normal (Yes in step S113, refer to FIG. 9), the space 60 between the gate valves is purged (step S115). In step S115, an inert gas such as a nitrogen gas is supplied into the space 60 between the gate valves from the gas supply 420 through the connector unit 43 and the connector unit 21 to purge the space 60 as shown in, for example, FIG. 15. The purging of the space 60 may be performed by alternately supplying and discharging the inert gas into and from the space 60 multiple times. This efficiently removes particles, moisture, and other matter in the space 60 between the gate valves.

The determination is then performed as to whether the difference between the pressure in the compartment 11 of the transporter 10 and the pressure in the space 60 between the gate valves is less than or equal to a predetermined value (step S116). In step S116, the determination is performed as to whether the difference between the pressure in the compartment 11 of the transporter 10 and the pressure in the space 60 between the gate valves has fallen to or below the predetermined value within a predetermined period from the start of evacuating the compartment 11 in step S105. In step S116, the pressure sensor included in the processing apparatus 40 measures the pressure in the compartment 11 of the transporter 10 and the pressure in the space 60 between the gate valves. The controller 41 in the processing apparatus 40 transmits an electric signal indicating the measurement result to the controller 150 in the transporter 10 through the connector unit 43 and the connector unit 21. The controller 150 in the transporter 10 determines, based on the received measurement result, whether the difference between the pressure in the compartment 11 of the transporter 10 and the pressure in the space 60 between the gate valves is less than or equal to the predetermined value.

In response to the difference between the pressure in the compartment 11 of the transporter 10 and the pressure in the space 60 between the gate valves being greater than the predetermined value (No in step S116), the processing in step S111 is performed.

In response to the difference between the pressure in the compartment 11 of the transporter 10 and the pressure in the space 60 between the gate valves being less than or equal to the predetermined value (Yes in step S116), the gate valve G1 in the transporter 10 is opened (step S117). The determination is then performed as to whether the difference between the pressure in the compartment 11 of the transporter 10 and the pressure in the plasma processing chamber 410 in the processing apparatus 40 is less than or equal to a predetermined value (step S118). In step S118, the pressure sensor included in the processing apparatus 40 measures the pressure in the plasma processing chamber 410.

In response to the difference between the pressure in the compartment 11 of the transporter 10 and the pressure in the plasma processing chamber 410 in the processing apparatus 40 being greater than the predetermined value (No in step S118), the processing in step S111 is performed.

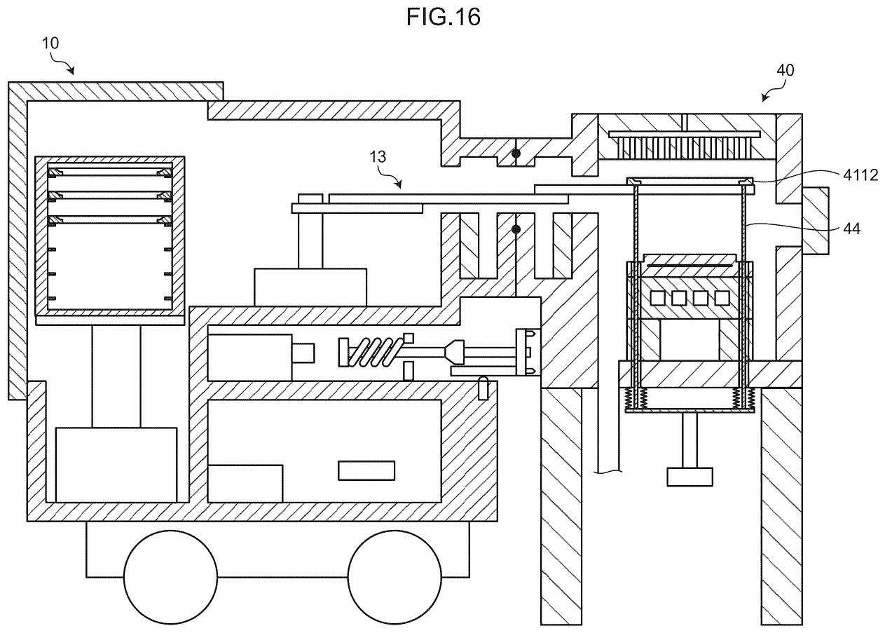

In response to the difference between the pressure in the compartment 11 of the transporter 10 and the pressure in the plasma processing chamber 410 in the processing apparatus 40 being less than or equal to the predetermined value (Yes in step S118), the gate valve G2 in the processing apparatus 40 is opened (step S119). The robotic arm 13 in the compartment 11 then replaces the wearable component (ring assembly 4112 in the example in FIG. 16) (step S120) as shown in, for example, FIG. 16.

After the wearable component is replaced, the gate valve G1 in the transporter 10 and the gate valve G2 in the processing apparatus 40 are closed (step S121). The evacuation of the space 60 between the gate valves is stopped (step S122). The space 60 between the gate valves is then purged (step S123). In step S123, the inert gas may be alternately supplied into and discharged from the space 60 multiple times as in step S115.

The determination is then performed as to whether the pressure in the space 60 between the gate valves has reached an atmospheric pressure and the concentration of the residual gas in the space 60 is lower than a predetermined value (step S124). The pipe between the connector unit 43 and the exhaust system 440 includes a sensor for measuring the concentration of a predetermined gas. The controller 41 in the processing apparatus 40 transmits, to the transporter 10 through the connector unit 43 and the connector unit 21, an electric signal indicating the measurement value from the sensor. In step S124, the determination is performed based on the measurement values received from the processing apparatus 40 as to whether the pressure in the space 60 between the gate valves has reached the atmospheric pressure and the concentration of the residual gas in the space 60 is lower than the predetermined value.

In response to the pressure in the space 60 between the gate valves not reaching the atmospheric pressure or the concentration of the residual gas in the space 60 being higher than or equal to the predetermined value (No in step S124), the processing in step S123 is performed again.

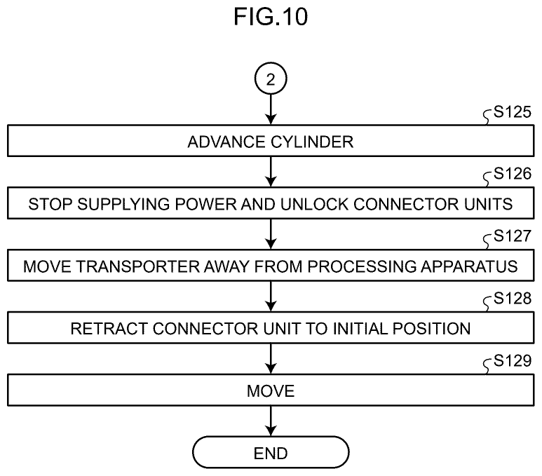

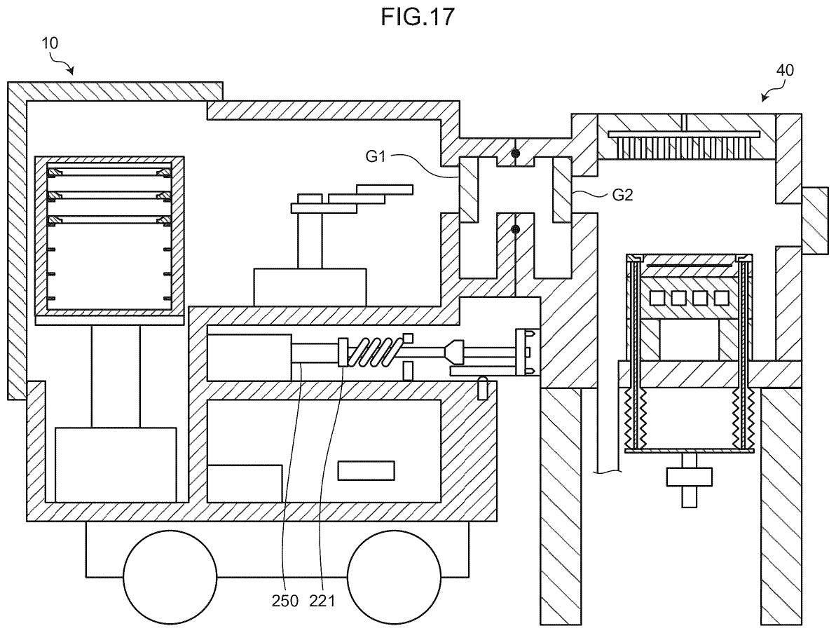

In response to the pressure in the space 60 between the gate valves having reached the atmospheric pressure and the concentration of the residual gas in the space 60 being lower than the predetermined value (Yes in step S124), the drive 25 advances the cylinder 250 (step S125, refer to FIG. 10). The cylinder 250 thus comes in contact with the coupler 221 as shown in, for example, FIG. 17.

Power supply to the transporter 10 is then stopped, and the connector unit 21 and the connector unit 43 are unlocked (step S126). The mover 14 then moves the transporter 10 away from the processing apparatus 40 (step S127).

Although the connector unit 21 and the connector unit 43 are unlocked, the connector unit 21 and the connector unit 43 adhering to each other may not be separated from each other. The connector unit 21 and the connector unit 43 may then remain in contact with each other as shown in, for example, FIG. 18 when the transporter 10 moves away from the processing apparatus 40.

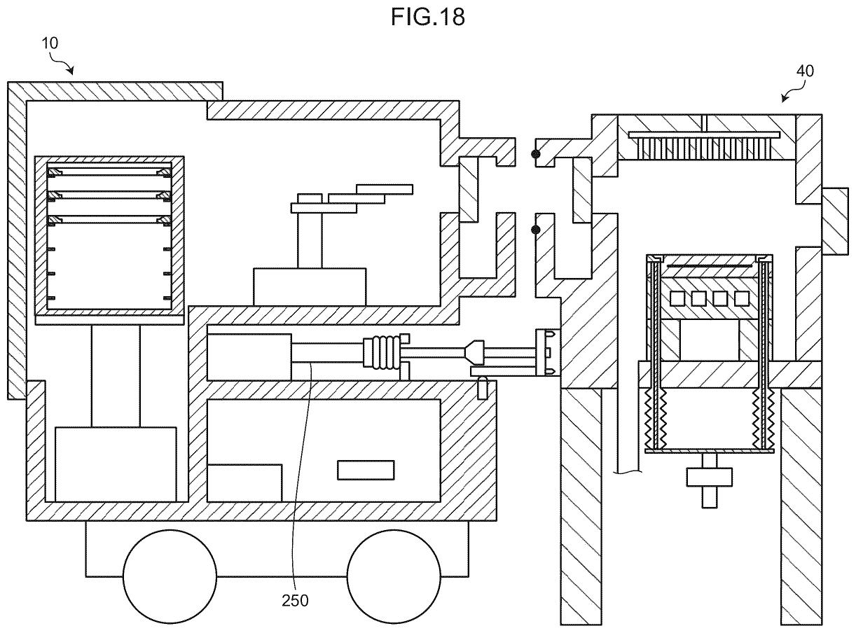

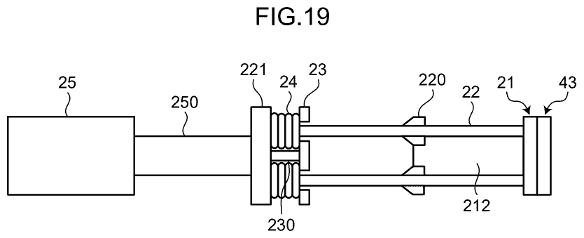

In this case, the coupler 221 and the bearing 23 are closer to each other as shown in, for example, FIG. 19 as the transporter 10 moves away from the processing apparatus 40. However, the distance between the coupler 221 and the bearing 23 is restricted by the stopper 230 and does not fall to or below a predetermined distance. Thus, the connector unit 21 and the connector unit 43 can be separated from each other when the transporter 10 moves further away from the processing apparatus 40.

In step S127, the drive 25 advances the cylinder 250 as the coupler 221 moves. Thus, the connector unit 21 and the connector unit 43 are separated from each other with a lower likelihood of a collision between the cylinder 250 and the coupler 221 that may occur when the coupler 221 and the bearing 23 are forcefully separated by a repulsive force from the springs 24.

The drive 25 then retracts the cylinder 250 to retract the connector unit 21 to its initial position (step S128). The mover 14 then moves the transporter 10 to its original position (step S129), and the transportation method shown in the flowchart ends.

### Travel Speed of Transporter 10

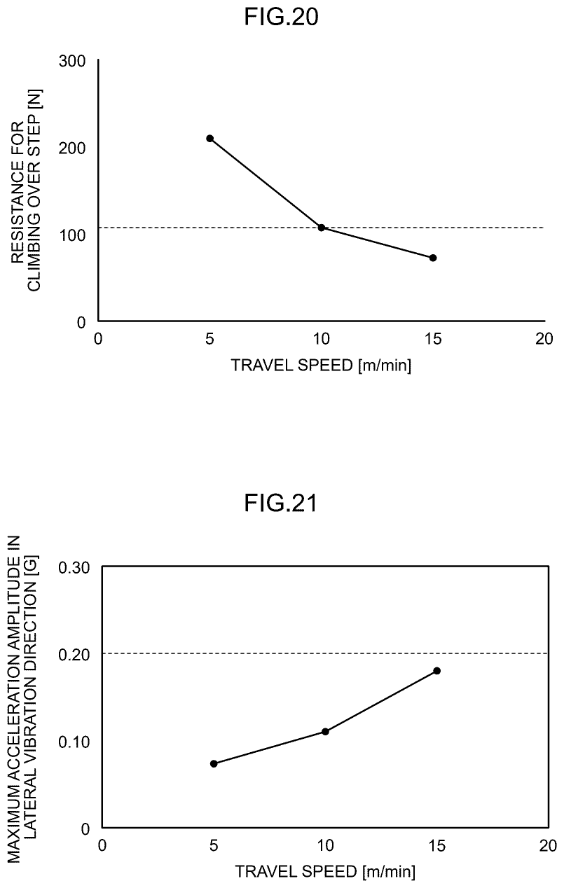

FIG. 20 is a graph showing an example relationship between the travel speed of the transporter 10 and the resistance for climbing over a step. As shown in, for example, FIG. 20, the transporter 10 at a lower travel speed is under a greater resistance to climb over a step, and has difficulty in climbing over a step. The transporter 10 at a higher travel speed is under a smaller resistance to climb over a step, and climbs over a step more easily. The resistance for climbing over a step may be less than or equal to 100 N. The transporter 10 may thus travel at a travel speed higher than or equal to 10 meters per minute.

FIG. 21 is a graph showing an example relationship between the travel speed of the transporter 10 and the maximum acceleration amplitude. As shown in, for example, FIG. 21, the transporter 10 at a higher travel speed has a greater maximum acceleration amplitude in a lateral vibration direction with respect to its travel direction. The wearable component may bounce in the cassette 12 during the travel. The wearable component bouncing in the cassette 12 during the travel may move to a different position or damaged. In contrast, the transporter 10 at a lower travel speed has a smaller maximum acceleration amplitude in the lateral vibration direction. The wearable component is less likely to bounce in the cassette 12 during the travel. To prevent the wearable component from bouncing in the cassette 12 during the travel, the maximum acceleration amplitude in the lateral vibration direction may be less than or equal to 0.2 G. To achieve this, the travel speed of the transporter 10 may be lower than or equal to 15 meters per minute. The transporter 10 traveling at a speed of 10 to 15 meters per minute inclusive may thus be under the resistance for climbing over a step of less than or equal to 100 N and have the maximum acceleration amplitude in the lateral vibration direction of less than or equal to 0.2 G.

An embodiment has been described above the transporter (transporter 10) according to the present embodiment described above transports the object (wearable component 30), and includes the compartment (compartment 11), the opening portion (opening portion 11a), the gate valve (gate valve G1), the robotic arm (robotic arm 13), the first connector unit (connector unit 21), the drive (drive 25), and the mover (mover 14). The compartment accommodates the object. The opening portion is connectable to the processing apparatus (processing apparatus 40) that processes the substrate (substrate W). The gate valve opens and closes the opening portion. The robotic arm is located in the compartment and includes the end effector (end effector 130) at its distal end to transfer the object with the end effector to and from the processing apparatus through the opening portion. The first connector unit includes the first connector (connector 211) to receive power to be supplied to the transporter from the external apparatus external to the transporter. The drive moves the first connector unit toward the second connector unit (connector unit 43) in the external apparatus to connect the first connector unit to the second connector unit. The mover moves the transporter. These structures can downsize the transporter.

The transporter according to the above embodiment includes the guide shaft (guide shaft 22) connected to the first connector unit, the bearing (bearing 23) having a through-hole with an inner diameter larger than the thickness of the guide shaft and supporting the guide shaft extending through the through-hole, and the support (support 26) supporting the first connector unit in a vertically movable manner. The drive moves the first connector unit with the guide shaft. The drive can thus move the first connector unit.

In the above embodiment, the first connector unit includes the first positioner engageable with the second positioner included in the second connector unit. The first connector unit and the second connector unit can thus be aligned easily to connect to each other.

In the above embodiment, the first connector unit includes at least one of the second connector (connector 211) to transmit and receive an electric signal to and from the external apparatus, the third connector (connector 211) to receive, from the external apparatus, a gas to be supplied into the compartment, or the fourth connector (connector 211) to discharge a gas from the compartment to the external apparatus. The multiple connectors can thus be connected at once.

The transporter according to the above embodiment includes the sensor (sensor 152) that senses the surroundings of the transporter, and the controller (controller 150) that controls the mover based on the sensing result from the sensor to move the transporter. The wearable component can thus be replaced efficiently.

In the above embodiment, the first connector unit retracts to a position in the transporter inward from the opening surface (surface 11c) of the opening portion when the transporter moves. The connectors in the connector unit 21 are thus less likely to break or leak electricity. Dust or other matter is thus less likely to adhere to the connectors in the connector unit 21.

In the above embodiment, the object is a wearable component to be used in the processing apparatus. In the above embodiment, the external apparatus is the processing apparatus. Thus, the battery in the transporter 10 can be, for example, charged when the wearable component in the processing apparatus is replaced.

In the above embodiment, the mover moves the transporter at a speed of 10 to 15 meters per minute inclusive. The transporter 10 can thus climb over a step easily, and the wearable component is less likely to bounce in the cassette 12 in the traveling transporter 10.

The connection method according to the above embodiment is a connection method for the transporter and includes steps (a), (b), (c), and (d). In step (a), the mover moves the transporter to a position adjacent to the processing apparatus. In step (b), the drive moves the first connector unit toward the second connector unit in the external apparatus. In step (c), the first connector unit connects to the second connector unit. In step (d), the mover moves the transporter toward the processing apparatus to connect the first opening portion to the second opening portion. These steps allow downsizing of the transporter.

### Others

The technique according to one or more embodiments described in the present application is not limited to the embodiment described above, and may be changed variously within the scope of the present disclosure.

For example, although the transporter 10 transports a wearable component such as the ring assembly 4112 to be used in the processing apparatus 40 in the above embodiment, the transporter 10 may transport an object other than a wearable component. The transporter 10 may transport an object such as a substrate W to be processed by the processing apparatus 40 or a substrate W processed by the processing apparatus 40.

Although the transporter 10 receives, for example, power supplied from the processing apparatus 40 through the connector unit 21 in the above embodiment, the technique according to one or more embodiments of the present disclosure is not limited to this example. In another embodiment, the transporter 10 may receive, for example, power supplied from a supply unit located in, for example, a clean room through the connector unit 21. The supply unit is an example of the external apparatus. The supply unit may be located adjacent to the processing apparatus 40. The transporter 10 can thus receive, for example, power supplied to the transporter 10 when the wearable component in the processing apparatus 40 is replaced.

Although the transporter 10 autonomously travels using the mover 14, the controller 150, and the sensor 152 in the above embodiment, the technique according to one or more embodiments of the present disclosure is not limited to this example. The transporter 10 may move based on the operation of a user. The mover 14 may be separable from the transporter 10. For example, a first portion including the transporter 10, the opening portion 11a, the gate valve G1, the robotic arm 13, the connector unit 21, and the drive 25 may be separable from a second portion including the mover 14.

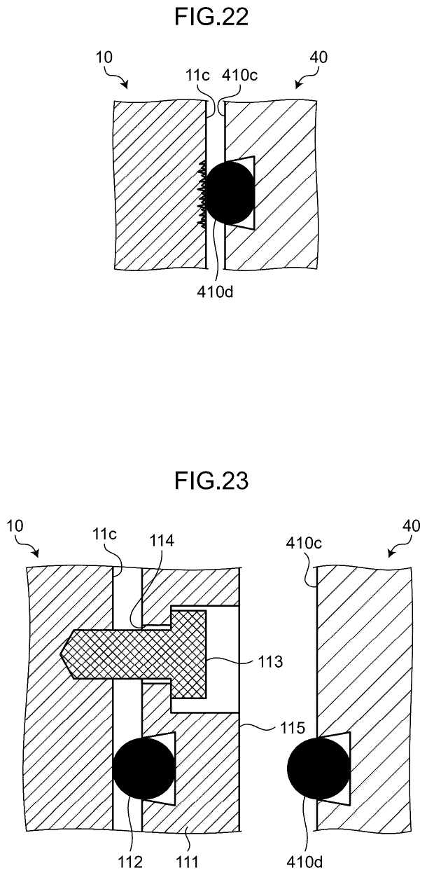

When the transporter 10 has a scratch on the surface 11c to be connected to the processing apparatus 40, the sealing performance of the O-ring 410d is lower for the opening portion 11a of the transporter 10 and the opening portion 410a of the processing apparatus 40 connected to each other as shown in, for example, FIG. 22. Thus, the entire housing including the surface 11c is to be replaced when the transporter 10 has a scratch on the surface 11c to be connected to the processing apparatus 40. Replacement of the entire housing including the surface 11c takes time.

The transporter 10 may thus include an annular member 111 on the surface 11c surrounding its opening portion 11a as shown in, for example, FIG. 23. An O-ring 112 is located between the annular member 111 and the surface 11c. The transporter 10 and the annular member 111 are fastened together with a screw 113. The annular member 111 has a clearance between a through-hole 114 receiving the screw 113 and the screw 113. The annular member 111 may be movable to compress the O-ring 112.

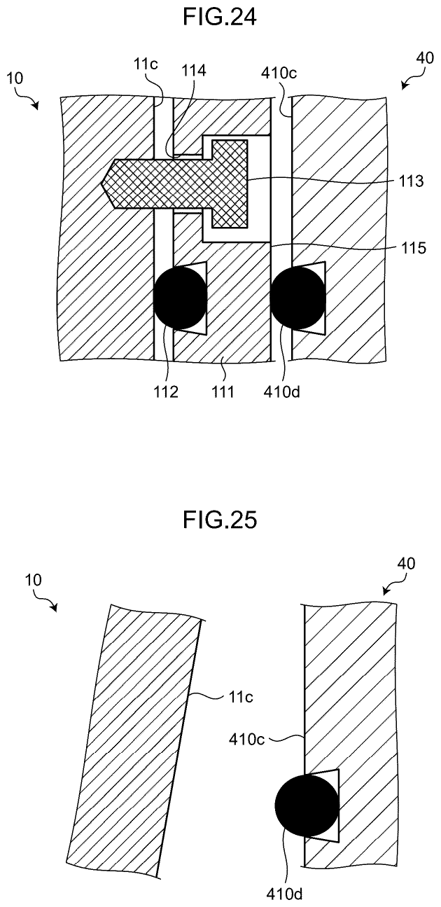

As shown in, for example, FIG. 24, the opening portion 11a of the transporter 10 and the opening portion 410a of the processing apparatus 40 connected to each other compress the O-ring 410d, and the annular member 111 is closer to the surface 410c of the processing apparatus 40. This structure allows the annular member 111 to be quickly replaced by unscrewing the screw 113 when the annular member 111 has a scratch on its surface 115.

When the surface 11c of the compartment 11 is inclined with respect to the surface 410c of the processing apparatus 40 as shown in, for example, FIG. 25, the opening portion 11a of the transporter 10 and the opening portion 410a of the processing apparatus 40 connected to each other do not compress the O-ring 410d sufficiently. This may lower the sealing performance of the O-ring 410d.

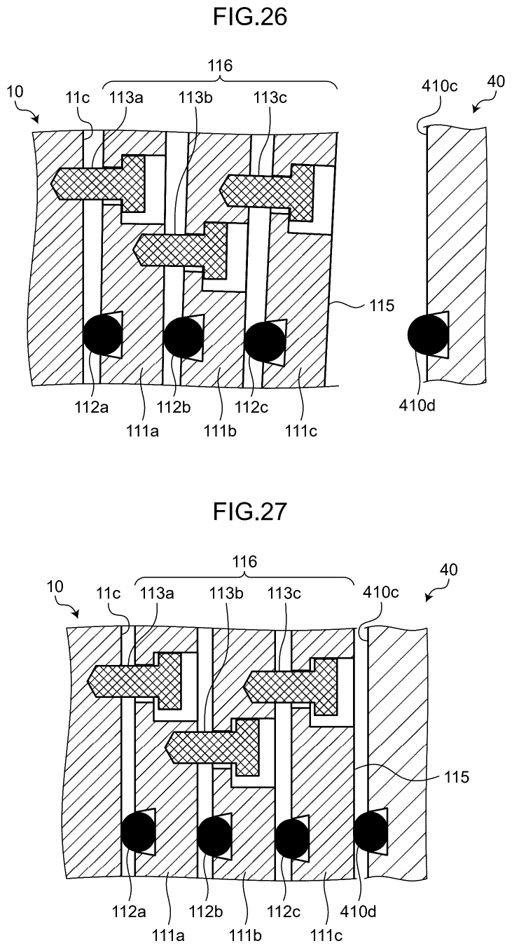

The transporter 10 may avoid this by including an annular seal unit 116 on the surface 11c surrounding the opening portion 11a as shown in, for example, FIG. 26 (herein “seal unit” means the same as “seal structure”). The seal unit 116 includes multiple annular members 111a to 111c, multiple O-rings 112a to 112c, and multiple screws 113a to 113c. Hereafter, the annular members 111a to 111c that are not distinguished from one another are collectively referred to as annular members 111. The O-rings 112a to 112c that are not distinguished from one another are collectively referred to as O-rings 112. The screws 113a to 113c that are not distinguished from one another are collectively referred to as screws 113.

The O-ring 112a is located between the annular member 111a and the surface 11c. The transporter 10 and the annular member 111a are fastened together with the screw 113a. The O-ring 112b is located between the annular member 111b and the annular member 111a. The annular member 111a and the annular member 111b are fastened together with the screw 113b. The O-ring 112c is located between the annular member 111c and the annular member 111b. The annular member 111b and the annular member 111c are fastened together with the screw 113c. Clearances are left between the screw 113a and the through-hole in the annular member 111a receiving the screw 113a, between the screw 113a and the through-hole in the annular member 111b receiving the screw 113b, and between the screw 113c and the through-hole in the annular member 111c receiving the screw 113c.

As shown in, for example, FIG. 27, the opening portion 11a of the transporter 10 and the opening portion 410a of the processing apparatus 40 connected to each other compress the O-ring 410d, and the annular member 111c is closer to the surface 410c of the processing apparatus 40. The O-ring 410d can thus be sufficiently compressed as shown in, for example, FIG. 27, although the surface 115 of the annular member 111c is inclined with respect to the surface 410c of the processing apparatus 40. The O-ring 410d is thus less likely to have lower sealing performance.

The transporter according to various aspects and embodiments of the present disclosure can be smaller.

The embodiments described herein are illustrative in all aspects and should not be construed to be restrictive. The above embodiments may be implemented in various forms. The components in the above embodiments may be eliminated, substituted, or modified in various forms without departing from the spirit and scope of the appended claims.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

Appendixes according to the above embodiments will be further described below.

### Appendix 1

A transporter for transporting an object, the transporter comprising:
a compartment configured to accommodate the object;
an opening portion connectable to a processing apparatus for processing a substrate;
a gate valve configured to open and close the opening portion;
a robotic arm in the compartment, the robotic arm including an end effector at a distal end of the robotic arm, the robotic arm being configured to transfer the object with the end effector to and from the processing apparatus through the opening portion;
a first connector unit including a first connector to receive power to be supplied to the transporter from an external apparatus external to the transporter;
a drive configured to advance the first connector unit toward a second connector unit in the external apparatus to connect the first connector unit to the second connector unit; and
a mover configured to move the transporter.

### Appendix 2

The transporter according to appendix 1, further comprising:
a guide shaft connected to the first connector unit;
a bearing having a through-hole with an inner diameter larger than a thickness of the guide shaft, the bearing supporting the guide shaft extending through the through-hole; and
a support supporting the first connector unit in a vertically movable manner,
wherein the drive moves the first connector unit with the guide shaft.

### Appendix 3

The transporter according to appendix 1 or appendix 2, wherein
the first connector unit includes a first positioner engageable with a second positioner included in the second connector unit.

### Appendix 4

The transporter according to any one of appendixes 1 to 3, wherein
the first connector unit includes at least one of
a second connector to transmit and receive an electric signal to and from the external apparatus,
a third connector to receive, from the external apparatus, a gas to be supplied into the compartment, or
a fourth connector to discharge a gas from the compartment to the external apparatus.

### Appendix 5

The transporter according to any one of appendixes 1 to 4, further comprising:
an O-ring along an outer circumference of the opening portion; and
an annular member along the O-ring.

### Appendix 6

The transporter according to appendix 5, further comprising:
a seal unit including a plurality of sets of the O-rings and the annular members connected to one another.

### Appendix 7

The transporter according to any one of appendixes 1 to 6, further comprising:
a sensor configured to sense surroundings of the transporter; and
a controller configured to move the transporter by controlling the mover based on a sensing result from the sensor.

### Appendix 8

The transporter according to any one of appendixes 1 to 7, wherein
the transporter is separable into
a first portion including the compartment, the opening portion, the gate valve, the robotic arm, the first connector unit, and the drive, and
a second portion including the mover.

### Appendix 9

The transporter according to any one of appendixes 1 to 8, wherein
the first connector unit retracts to a position in the transporter inward from an opening surface of the opening portion when the transporter moves.

### Appendix 10

The transporter according to any one of appendixes 1 to 9, wherein
the object is a wearable component used in the processing apparatus.

### Appendix 11

The transporter according to any one of appendixes 1 to 10, wherein
the external apparatus is the processing apparatus.

### Appendix 12

The transporter according to any one of appendixes 1 to 11, wherein
the mover moves the transporter at a speed of 10 to 15 m per minute inclusive.

### Appendix 13

A connection method for a transporter, the transporter including a compartment to accommodate an object, a first opening portion connectable to a second opening portion of a processing apparatus for processing a substrate, a gate valve to open and close the first opening portion, a robotic arm located in the compartment and including an end effector at a distal end of the robotic arm to transfer the object with the end effector to and from the processing apparatus through the first opening portion, a first connector unit including a first connector to receive power to be supplied to the transporter from an external apparatus external to the transporter, a drive to move the first connector unit, and a mover to move the transporter, the method comprising:
(a) moving, with the mover, the transporter to a position adjacent to the processing apparatus;
(b) advancing, with the drive, the first connector unit toward a second connector unit in the external apparatus;
(c) connecting the first connector unit to the second connector unit; and
(d) moving, with the mover, the transporter toward the processing apparatus and connecting the first opening portion to the second opening portion.

What is claimed is:

1. A transporter for transporting an object, the transporter comprising:
a compartment to accommodate the object;
an opening portion connectable to a processing apparatus for processing a substrate;
a gate valve to open and close the opening portion;
a robotic arm in the compartment, the robotic arm including an end effector at a distal end of the robotic arm, the robotic arm to transfer the object with the end effector to and from the processing apparatus through the opening portion;
a first connector structure including a first connector to receive power to be supplied to the transporter from an external apparatus external to the transporter;
a drive configured to advance the first connector structure toward a second connector structure in the external apparatus to connect the first connector structure to the second connector structure;
a mover configured to move the transporter; and
controller circuitry configured to control the drive, the controller circuitry configured to cause the drive to connect the first connector structure to the second connector structure before the opening portion is connected to the processing apparatus.

2. The transporter according to claim 1, further comprising:
a guide shaft connected to the first connector structure; and
a bearing having a through-hole with an inner diameter larger than a thickness of the guide shaft, the bearing supporting the guide shaft extending through the through-hole,
wherein the drive moves the first connector structure with the guide shaft.

3. The transporter according to claim 2, further comprising:
a support supporting the first connector structure in a vertically movable manner.

4. The transporter according to claim 1, wherein
the first connector structure includes a first positioner engageable with a second positioner included in the second connector structure.

5. The transporter according to claim 1, wherein
the first connector structure includes at least one of
a second connector to transmit and receive an electric signal to and from the external apparatus,
a third connector to receive, from the external apparatus, a gas to be supplied into the compartment, or
a fourth connector to discharge a gas from the compartment to the external apparatus.

6. The transporter according to claim 1, further comprising:
an O-ring along an outer circumference of the opening portion; and
an annular structure along the O-ring.

7. The transporter according to claim 6, further comprising:
a seal structure including a plurality of sets of the O-rings and the annular structures connected to one another.

8. The transporter according to claim 1, further comprising:
a sensor configured to sense surroundings of the transporter; and
the controller circuitry is configured to move the transporter by controlling the mover based on a sensing result from the sensor.

9. The transporter according to claim 1, wherein
the transporter is separable into
a first portion including the compartment, the opening portion, the gate valve, the robotic arm, the first connector structure, and the drive, and
a second portion including the mover.

10. The transporter according to claim 1, wherein
the first connector structure retracts to a position in the transporter inward from an opening surface of the opening portion when the transporter moves.

11. The transporter according to claim 1, wherein
the object is a wearable component used in the processing apparatus.

12. The transporter according to claim 1, wherein
the external apparatus is the processing apparatus.

13. The transporter according to claim 1, wherein
the mover moves the transporter at a speed of 10 to 15 meters per minute inclusive.

14. A connection method for a transporter, the method comprising:
moving, with a mover, the transporter to a position adjacent to a processing apparatus for processing a substrate, the transporter including a compartment to accommodate an object, a first opening portion connectable to a second opening portion of the processing apparatus, a gate valve to open and close the first opening portion, a robotic arm located in the compartment and including an end effector at a distal end of the robotic arm to transfer the object with the end effector to and from the processing apparatus through the first opening portion, a first connector structure including a first connector to receive power to be supplied to the transporter from an external apparatus external to the transporter, a drive to move the first connector structure, and the mover to move the transporter;
advancing, with the drive, the first connector structure toward a second connector structure in the external apparatus;
connecting the first connector structure to the second connector structure; and
connecting the first opening portion to the second opening portion.

15. A processing system, comprising:
a processing apparatus configured to process a substrate; and
a transporter configured to transport an object, the transporter including
a compartment to accommodate the object,
an opening portion connectable to the processing apparatus,
a gate valve to open and close the opening portion,
a robotic arm in the compartment, the robotic arm including an end effector at a distal end of the robotic arm, the robotic arm to transfer the object with the end effector to and from the processing apparatus through the opening portion,
a first connector structure including a first connector to receive power to be supplied to the transporter from an external apparatus external to the transporter,
a drive configured to advance the first connector structure toward a second connector structure in the external apparatus to connect the first connector structure to the second connector structure,
a mover configured to move the transporter, and
controller circuitry configured to control the drive, the controller circuitry is configured to cause the drive to connect the first connector structure to the second connector structure before the opening portion is connected to the processing apparatus.
